(19) United States
(12) Patent Application Publication
(10) Pub. No.: US 2021/0328083 A1
(43) Pub. Date: Oct. 21, 2021

(54) OPTOELECTRONIC DEVICES HAVING AN ELECTRODE WITH APERTURES

(71) Applicant: GLOBALFOUNDRIES Singapore Pte. Ltd., Singapore (SG)

(72) Inventors: SANDIPTA ROY, Singapore (SG); KHEE YONG LIM, Singapore (SG); KIOK BOONE ELGIN QUEK, Singapore (SG)

(21) Appl. No.: 16/852,551

(22) Filed: Apr. 20, 2020

(51) Int. Cl. H01L 31/0224; H01L 31/0216

(52) U.S. Cl. CPC H01L 31/022408; H01L 31/0216

(57) ABSTRACT

The present disclosure generally relates to structures and semiconductor devices for use in optoelectronic/photonic applications and integrated circuit (IC) chips. More particularly, the present disclosure relates to optoelectronic devices having an electrode that is capable of filtering electromagnetic waves. The present disclosure provides a structure having a substrate, an optical detector upon the substrate, and an electrode upon an upper surface of the optical detector. The electrode defines at least one aperture configured to filter electromagnetic waves traversing the aperture. The optical detector is structured to detect the electromagnetic waves filtered by the aperture.

### FIELD OF THE INVENTION

The present disclosure generally relates to structures and semiconductor devices for use in optoelectronic/photonic applications and integrated circuit (IC) chips. More particularly, the present disclosure relates to optoelectronic devices having an electrode that is capable of filtering electromagnetic waves. The present disclosure also relates to methods of forming such devices.

### BACKGROUND

Optoelectronic or photonic devices are a type of semiconductor device that detects and harnesses electromagnetic energy such as light. The use of such devices in high-speed switching and transceiver devices in data communications are but a few examples that highlight the advantages of processing both optical and electrical signals within a single integrated circuit (IC) device.

Ideally, it is desirable to have an integrated optoelectronic device that achieves light absorption efficiency as close as possible to 100 percent to obtain maximum device sensitivity. However, structures that are formed to provide electrical connections between various device components are found to block or reduce light to be absorbed by the photonic component of the IC device, which may decrease its sensitivity and the overall device performance. To prevent blockage of light, these electrical connections may be removed or re-built around the photonic component. However, such a solution requires multiple lithographic steps to achieve which is costly and cumbersome.

Therefore, there is a need to provide structures and semiconductor devices that can overcome, or at least ameliorate, one or more of the disadvantages as described above.

### SUMMARY

In an aspect of the present disclosure, there is provided a structure having a substrate, an optical detector upon the substrate, and an electrode upon an upper surface of the optical detector. The electrode defines at least one aperture configured to filter electromagnetic waves traversing the aperture. The optical detector is structured to detect the electromagnetic waves filtered by the aperture.

In another aspect of the present disclosure, there is provided a semiconductor device having a substrate, an optical detector upon the substrate, an electrode upon an upper surface of the optical detector, the electrode defining at least one aperture configured to filter electromagnetic waves traversing the aperture, in which the optical detector is structured to detect the electromagnetic waves filtered by the aperture, a dielectric material that fills the aperture, and a logic device component electrically connected to the optical detector through the electrode.

In yet another aspect of the present disclosure, there is provided a method of forming a semiconductor device by forming an optical detector on a substrate, forming an electrode upon an upper surface of the optical detector, the electrode defining at least one aperture configured to filter electromagnetic waves traversing the aperture, in which the optical detector detects the electromagnetic waves filtered by the aperture, connecting a logic device component with the optical detector through the electrode.

### BRIEF DESCRIPTION OF THE DRAWINGS

The present disclosure may be understood by reference to the following description taken in conjunction with the accompanying drawings.

For simplicity and clarity of illustration, the drawings illustrate the general manner of construction, and certain descriptions and details of well-known features and techniques may be omitted to avoid unnecessarily obscuring the discussion of the described embodiments of the present disclosure. Additionally, elements in the drawings are not necessarily drawn to scale. For example, the dimensions of some of the elements in the drawings may be exaggerated relative to other elements to help improve understanding of embodiments of the present disclosure. The same reference numerals in different drawings denote the same elements, while similar reference numerals may, but do not necessarily, denote similar elements.

FIG. 1 is a top view depicting a structure for use in optoelectronic/photonic applications, in accordance with embodiments of the present disclosure.

FIG. 2A and FIG. 2B depict cross-sectional views of the structure shown in FIG. 1, in accordance with the present disclosure. FIG. 2A is the cross-section taken along section line A-A′ in FIG. 1, while FIG. 2B is the cross-section taken along section line B-B′ in FIG. 1.

FIG. 3 is a cross-sectional view depicting an exemplary arrangement of a semiconductor device having a logic device component electrically connected to an optical detector, in accordance with the present disclosure.

FIG. 4 is a cross-sectional view depicting another exemplary arrangement of a semiconductor device having a logic device component electrically connected to an optical detector, in accordance with the present disclosure.

FIG. 5A to FIG. 5G are cross-sectional views depicting various stages of forming a semiconductor device shown in FIG. 3, in accordance with the present disclosure.

### DETAILED DESCRIPTION

Various illustrative embodiments of the present disclosure are described below. The embodiments disclosed herein are exemplary and not intended to be exhaustive or limiting to the present disclosure.

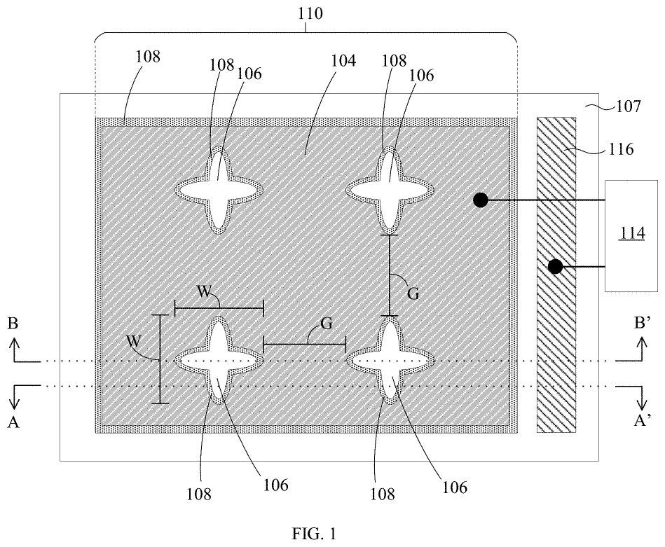

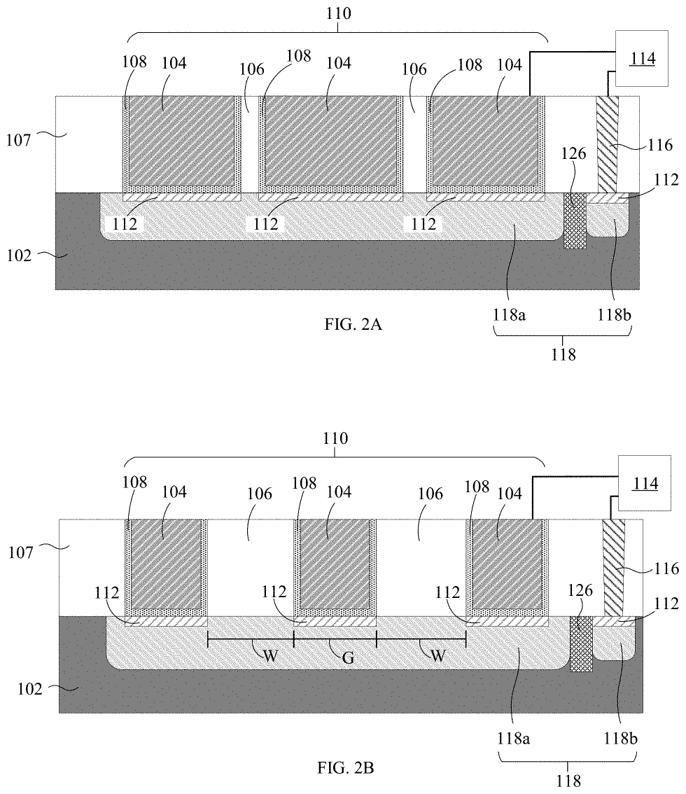

Referring to FIG. 1, FIG. 2A and FIG. 2B, a structure for use in optoelectronic/photonic applications includes a substrate 102, an optical detector 118 arranged upon the substrate 102, and an electrode 110 arranged upon an upper surface of the optical detector 118. The electrode 110 may be formed within a dielectric layer 107.

The electrode 110 defines at least one aperture 106 configured to filter electromagnetic waves traversing the aperture 106. In the representative embodiments, the electrode 110 defines a plurality of apertures 106 arranged in a matrix arrangement. For example, as shown in FIG. 1, the plurality of apertures 106 may be arranged in a 2 by 2 matrix. Other matrix sizes may also be contemplated for the arrangement of the plurality of apertures 106. Although not shown in the accompanying drawings, it should be understood that the present disclosure also contemplates an electrode that defines a single aperture configured for filtering electromagnetic waves.

The plurality of apertures 106 may be arranged according to a given periodicity. In particular, each aperture 106 has a width W and adjacent apertures 106 are separated from each other by a gap G. The width W and the gap G define the periodicity of the plurality of apertures 106. As shown in FIG. 1, the plurality of apertures 106 has a periodic arrangement. The width W and the gap G of the plurality of apertures 106 may be configured to have dimensions in the nanoscale (e.g., hundredths of nanometers) to filter electromagnetic waves. The width W and the gap G of the apertures 106 may be modified depending on the wavelength of the electromagnetic wave that is allowed to filter through the aperture 106.

Each aperture 106 may be shaped like a pair of elliptical openings that intersect with each other. Preferably, the pair of elliptical openings may intersect each other perpendicularly. In the embodiment shown in FIG. 1, the apertures 106 are cross-shaped apertures with rounded tips. The provision of rounded tips may avoid parasitic effects (e.g., “sharp” electric field effect) at the tips of the apertures 106, and also prevents optical proximity correction error during lithographic steps. Therefore, the provision of rounded tips and the arrangement of the electrode 110 upon the upper surface of the optical detector 118 may reduce the timing jitter in a photodiode and increases the sensitivity of an optoelectronic device.

Each aperture 106 may be filled with a dielectric material having a refractive index in the range of about 1.4 to about 2, preferably in the range of 1.46 to 2. Examples of the dielectric material that fills the aperture may include, but not limited to, silicon dioxide, silicon nitride, or tetraethyl orthosilicate (TEOS). In some embodiments, the dielectric layer 107 may be of the same dielectric material that fills the apertures 106.

The electrode 110 may include a conductive barrier layer 108 and a metal layer 104 arranged upon the conductive barrier layer 108. The metal layer 104 may include a metallic compound such as copper, aluminum, or an alloy thereof. The conductive barrier layer 108 may function to prevent diffusion of atoms between the metal layer 104 and the optical detector 118, whilst allowing electrical conduction between the metal layer 104 and the optical detector 118. Examples of materials for the conductive barrier layer 108 may include, but not limited to, titanium nitride (TiN), or tantalum nitride (TaN).

The optical detector 118 may be structured to detect the electromagnetic waves filtered by the apertures 106. The optical detector 118 may include a diode having a first conductivity region 118a and a second conductivity region 118b. For example, the optical detector 118 may include a photodiode (PD), an avalanche photodiode (APD), or a single-photon avalanche diode (SPAD). The first conductivity region 118a and the second conductivity region 118b may have opposite conductivity types (e.g., P-type and N-type conductivities) and may be separated from each other by an isolation structure 126.

A silicide layer 112 may be formed upon upper surfaces of the optical detector 118 (e.g., the first conductivity region 118a and the second conductivity region 118b). The conductive barrier layer 108 may be arranged directly on the upper surface of the first conductivity region 118a. In some embodiments, the conductive barrier layer 108 may be preferably arranged directly on the silicide layer 112 that is formed upon the first conductivity region 118a.

A contact structure 116 may be arranged directly on the second conductivity region 118b. The electrode 110 and the contact structure 116 may function as either an anode or a cathode, respectively, depending on the conductivity types of the first conductivity regions 118a and the second conductivity region 118b. The electrode 110 and the contact structure 116 may provide electrical connections between the optical detector 118 and other circuitry components in the semiconductor device, such as a logic device component 114.

The substrate 102 may be made of any semiconductor material, such as silicon, germanium, silicon germanium (SiGe), silicon carbide, and those consisting essentially of III-V compound semiconductors, such as GaAs, II-VI compound semiconductors such as ZnSe. A portion or the entire substrate 102 may be amorphous, polycrystalline, or monocrystalline. The substrate 102 may be doped and may include various doped regions.

Advantageously, the inclusion of the electrode 110 having at least one aperture 106 is found to provide both electrical connections for the optical detector 118 with other circuitry components in an optoelectronic device, as well as filtering of electromagnetic waves to be absorbed by the optical detector 118. Additionally, the use of the electrode 110 as an optical filter avoids the need to fabricate an additional optical filter layer arranged separately above the optical detector 118 (which would require multiple lithographic steps), thereby reducing the overall fabrication cost.

More advantageously, the arrangement of the electrode 110 is found to enhance the absorption of electromagnetic waves by the optical detector 118. For example, the arrangement of the electrode 110 on and directly contacting the optical detector 118 is found to confine electromagnetic waves (i.e., photons) in shallow regions at the upper surface of the optical detector 118 for absorption, which reduces the thickness/depth of the substrate 102 and the region traversed by the absorbed photons. The absorbed photons may travel a shorter distance to reach the metal layer 104 in the electrode 110, thereby reducing the arrival time of a detected photon and resulting in higher sensitivity and lower jitter of the detector and better overall device performance.

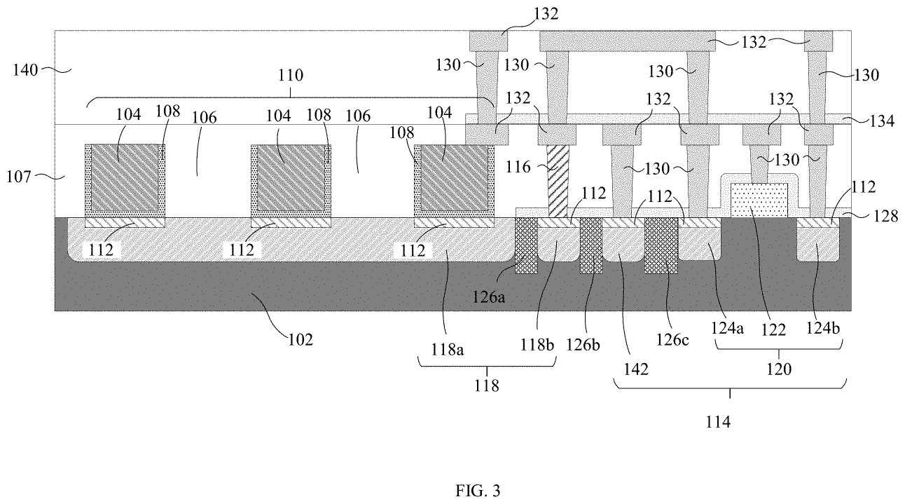

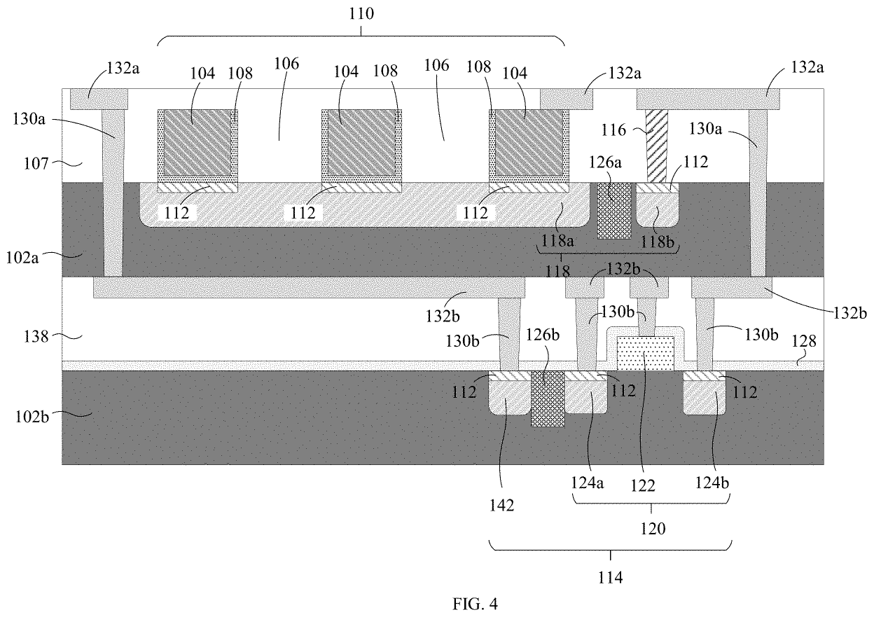

FIG. 3 and FIG. 4 illustrate exemplary arrangements of a semiconductor device having a logic device component 114 electrically connected to an optical detector 118.

In the embodiment shown in FIG. 3, the semiconductor device includes a substrate 102, an optical detector 118 arranged upon the substrate 102, an electrode 110 arranged upon an upper surface of the optical detector 118, and a contact structure 116 arranged upon an upper surface of the optical detector 118.

The logic device component 114 may function as a light to digital converter and may include a transistor 120 and a bias terminal 142. The transistor 120 may include a gate 122 arranged between source and drain regions 124a, 124b. The bias terminal 142 may function to control the electrical bias of the substrate 102 and may be connected to a floating electrode (not shown). As shown in FIG. 3, the logic device component 114 may be arranged on the same substrate 102 as the optical detector 118. The contact structure 116 may connect the transistor 120 with the second conductivity region 118b of the optical detector 118.

In some embodiments (not shown), the logic device component 114 may also include a high voltage transistor. The electrode 110 may connect the high voltage transistor with the first conductivity region 118a of the optical detector 118. The high voltage transistor may be configured to operate at voltages above 5V. Examples of high voltage transistors may include, but not limited to, a laterally diffused metal-oxide semiconductor (LDMOS), and a lateral extended drain metal-oxide semiconductor (EDMOS). For simplicity, the structural arrangement of the high voltage transistor is not shown in FIG. 3.

Isolation structures 126a, 126b, 126c may be formed in the substrate 102 to separate the first conductivity region 118a, the second conductivity region 118b, the bias terminal 142, and the source and drain regions 124a, 124b. Silicide layers 112 may be formed on upper surfaces of the bias terminal 142, and the source and drain regions 124a, 124b. In some embodiments, the silicide layers 112 may be defined as thin silicide layers having a thickness in the range of about 3 nm to about 5 nm. Interconnect structures, such as vias 130 and conductive lines 132 may be formed within dielectric layers 107, 140 for connecting the electrode 110, the contact structure 116 with the transistor 120 and the bias terminal 142.

In the embodiment shown in FIG. 4, the semiconductor device includes an optical detector 118 arranged upon a first substrate 102a, an electrode 110 arranged upon an upper surface of the optical detector 118, and a contact structure 116 arranged upon an upper surface of the optical detector 118. The semiconductor device also includes a logic device component 114 arranged upon a second substrate 102b. The logic device component 114 may be electrically connected to the second conductivity region 118b of the optical detector 118 by the contact structure 116. As shown, the logic device component 114 and the optical detector 118 are arranged on different substrates. Similar to FIG. 3, the logic device component 114 may also include a high voltage transistor (not shown). The electrode 110 may connect the high voltage transistor with the first conductivity region 118a of the optical detector 118. For simplicity, the structural arrangement of the high voltage transistor is not shown in FIG. 4.

The embodiment shown in FIG. 4 may be fabricated by wafer bonding techniques. For example, the electrode 110, the optical detector 118 and interconnect structures (e.g., vias 130a and conductive lines 132b) may be fabricated on the first substrate 102a. The logic device component 114 and the interconnect structures (e.g., vias 130b and conductive lines 132b) may be fabricated on the second substrate 102b.

As shown, the vias 130a of the first substrate 102a may be through-substrate vias that pass through the first substrate 102a for bonding with the conductive lines 132b of the second substrate 102b. Heat treatment processes, such as an annealing step, may be performed for bonding the vias 130a with the conductive lines 132b.

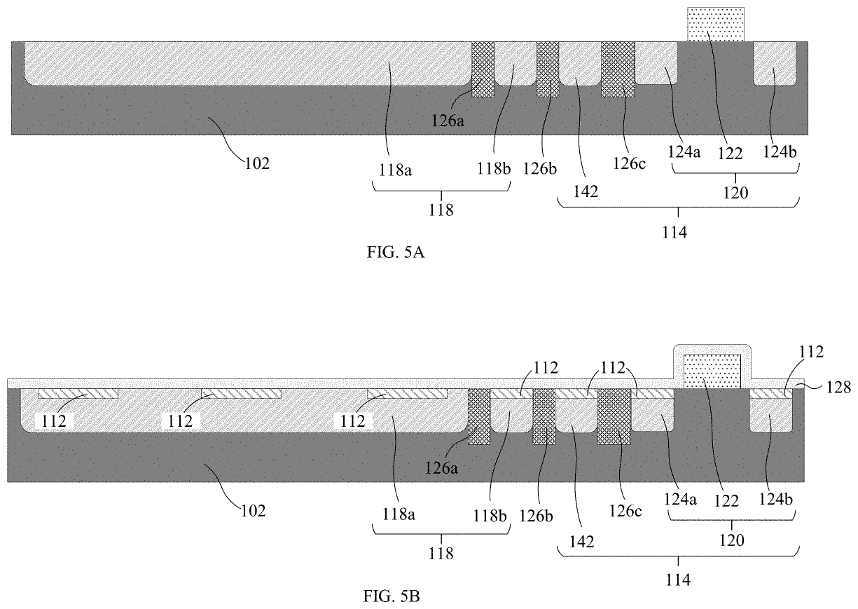

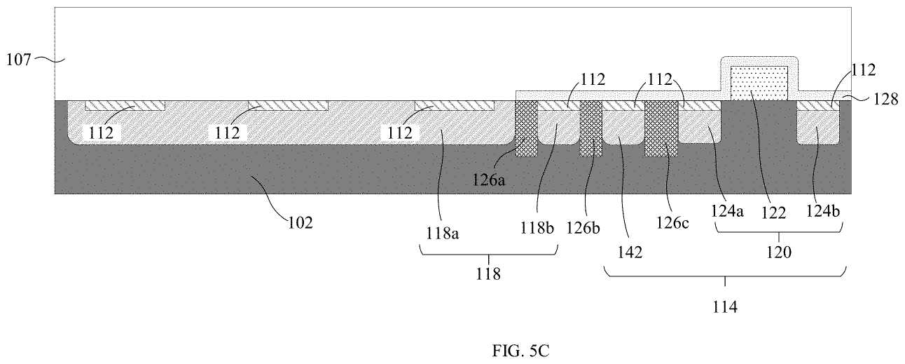

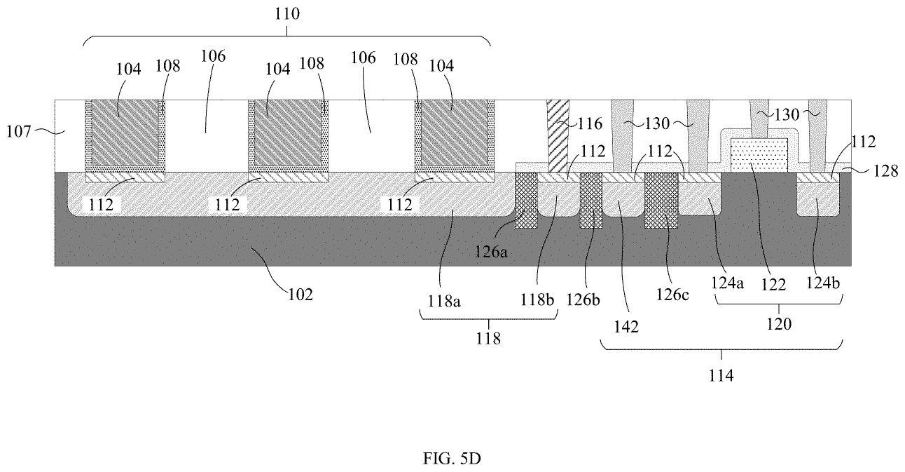

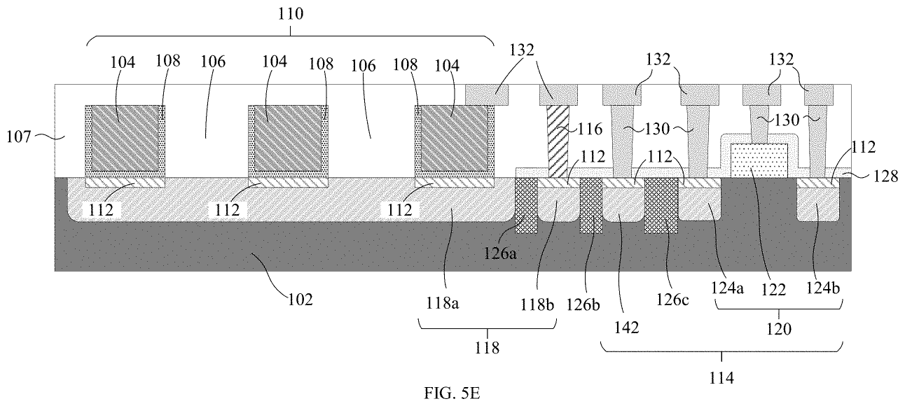

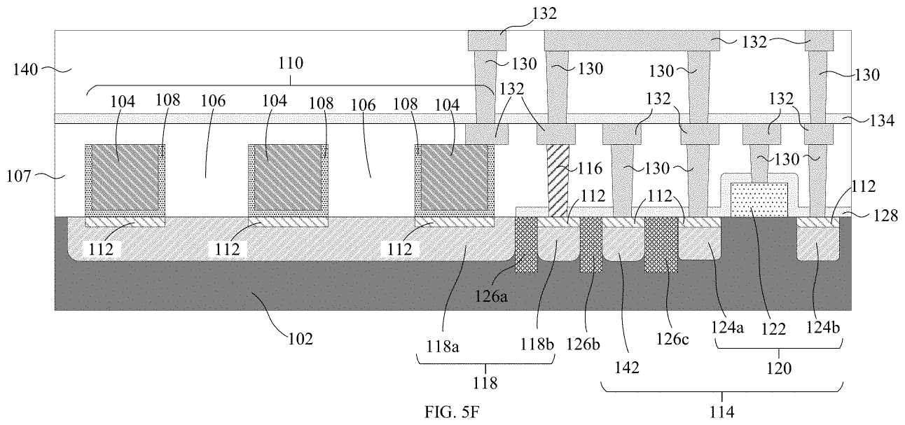

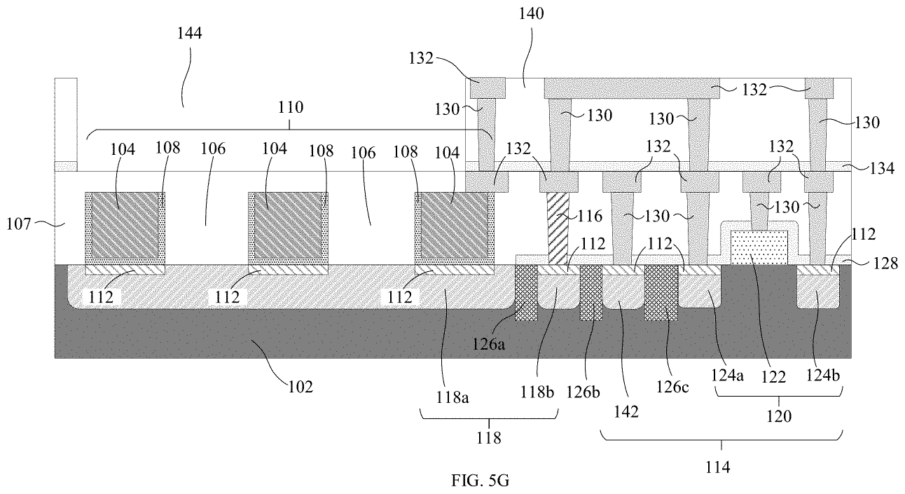

FIGS. 5A through 5G show a set of steps that could be used to create the embodiment shown in FIG. 3, in accordance with the present disclosure.

As used herein, “patterning techniques” includes deposition of material or photoresist, patterning, exposure, development, etching, cleaning, and/or removal of the material or photoresist as required in forming a described pattern, structure or opening. Examples of techniques for patterning include, but not limited to, wet etch lithographic processes, dry etch lithographic processes or direct patterning processes. Such techniques may use mask sets and mask layers.

Additionally, “deposition techniques” refer to the process of applying a material over another material (or the substrate). Exemplary techniques for deposition include, but not limited to, spin-on coating, sputtering, chemical vapor deposition (CVD), physical vapor deposition (PVD), molecular beam deposition (MBD), pulsed laser deposition (PLD), liquid source misted chemical deposition (LSMCD), atomic layer deposition (ALD).

Referring to FIG. 5A, a substrate 102 having isolation structures 126a, 126b, 126c may be provided. An optical detector 118 and a logic device component 114 may be formed on the substrate 102. The optical detector 118 may include a first conductivity region 118a and a second conductivity region 118b. The logic device component 114 may include a bias terminal 142 and a transistor 120 that has source and drain regions 124a, 124b. The first conductivity region 118a, the second conductivity region 118b, the bias terminal 142, and the source and drain regions 124a, 124b may be formed by doping an upper surface of the substrate 102 (e.g., using ion implantation) using dopants. Masks or reticles may additionally be used during the doping processes. A gate 122 may be formed upon the substrate 102 and is positioned between the source and drain regions 124a, 124b.

Various dopant conductivity types may be used for doping, such as P-type and N-type. Exemplary dopants for N-type conductivity doping may include, but not limited to, arsenic, phosphorus, or antimony. Exemplary dopants for P-type conductivity doping may include, but not limited to, boron, aluminum, or gallium. Additionally, the first conductivity region 118a, the second conductivity region 118b, the bias terminal 142, and the source and drain regions 124a, 124b may have various depths and dopant concentrations depending on the technology node and design requirements.

Referring to FIG. 5B, silicide layers 112 may be formed on upper surfaces of the first conductivity region 118a, the second conductivity region 118b, the bias terminal 142, and the source and drain regions 124a, 124b. Subsequently, an etch stop layer 128 may be formed using deposition processes to cover the optical detector 118 and the logic device component 114. The etch stop layer 128 may be a silicon nitride layer.

Referring to FIG. 5C, a portion of the deposited etch stop layer 128 may be removed (e.g., using an etching process) to expose the optical detector 118, whereas the portion of the etch stop layer 128 covering the second conductivity region 118b, the bias terminal 142, and the transistor 120 may be retained. A dielectric layer 107 may be formed upon the upper surface of the optical detector 118 and the remaining portion of the etch stop layer 128.

Referring to FIG. 5D, an electrode 110, a contact structure 116, and vias 130 may be formed within the dielectric layer 107. The electrode 110 may be formed on the first conductivity region 118a and the contact structure 116 may be formed on the second conductivity region 118b. The vias 130 may be formed on the bias terminal 142, the gate 122 and the source and drain regions 124a, 124b.

To form the electrode 110, the contact structure 116 and the vias 130, for example, the dielectric layer 107 may be patterned using patterning techniques to form openings (not shown), followed by filling the openings using deposition techniques. In particular, the patterning of the dielectric layer 107 forms openings above an upper surface of the optical detector 118. The openings are subsequently filled with a conductive barrier layer 108 and a metal layer 104. The conductive barrier layer 108 may be deposited within the openings and directly contact the silicide layers 112 on the first conductivity region 118a. The metal layer 104 may be deposited on the conductive barrier layer 108. The deposited conductive barrier layer 108 may have a non-uniform thickness due to conformality issues during the deposition process. For example, the portion of the conductive barrier layer 108 deposited on the sidewalls of the openings may be thinner than the portion of the conductive barrier layer 108 deposited upon the upper surface of the optical detector 118.

The formed electrode 110 also defines apertures 106, as described in FIG. 1, which may include the same dielectric material as the dielectric layer 107. The dimensions of the apertures 106 may be adjusted during the patterning of the dielectric layer 107 and depend on the wavelength of electromagnetic waves allowed to traverse through the apertures 106.

The patterning of the dielectric layer 107 also forms openings (not shown) above the second conductivity region 118b, the bias terminal 142, the gate 122 and the source and drain regions 124a, 124b. A metallic material such as copper, cobalt, aluminum or an alloy thereof may be deposited in the openings to form the contact structure 116 and the vias 130.

A chemical mechanical polishing step may be subsequently performed to planarize the upper surfaces of the electrode 110, the contact structure 116 and the vias 130 with the upper surface of the dielectric layer 107.

Referring to FIG. 5E, an additional dielectric material may be deposited on the dielectric layer 107. Conductive lines 132 may be formed within the deposited dielectric material 107 to connect the electrode 110, the contact structure 116, and vias 130.

FIG. 5F illustrates connecting the logic device component 114 to the optical detector 118. As shown, an etch stop layer 134 may be deposited on the dielectric layer 107 and a dielectric layer 140 may be deposited on the etch stop layer 134. Interconnect structures such as vias 130 and conductive lines 132 may be formed within the dielectric layer 140 by performing similar processing steps described in FIG. 5D. The etch stop layer 134 and the dielectric layer 140 that embeds the interconnect structures may be part of a “metallization layer”. Although not shown in the accompanying drawings, multiple metallization layers may be formed in a vertical stack configuration above the dielectric layer 140, depending on design requirements. The interconnect structures within the multiple metallization layers may serve to provide electrical connections between the optical detector 118, the logic device component 114, and other device components fabricated in an IC chip.

Referring to FIG. 5G, an etching step (i.e., a “canyon” etch) may be performed to a portion of the etch stop layer 134 above the electrode 110. The etching step may be performed using various etching techniques, such as reactive ion etching, and forms a “canyon” opening 144 positioned above the electrode 110. The etching of the portion of the etch stop layer 134 may serve to prevent blockage of electromagnetic waves traversing towards the electrode 110. Subsequently, the “canyon” opening 144 is filled with a dielectric material to form the embodiment shown in FIG. 3.

Throughout this disclosure, the terms top, upper, upwards, over, and above refer to the direction away from the substrate. Likewise, the terms bottom, lower, downwards, under, and below refer to the direction towards the substrate. It is to be understood that the terms so used are interchangeable under appropriate circumstances such that the embodiments of the device described herein are, for example, capable of operation in other orientations than those illustrated or otherwise described herein.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in an embodiment” herein do not necessarily all refer to the same embodiment.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. Furthermore, there is no intention to be bound by any theory presented in the preceding background or the following detailed description.

Additionally, the various tasks and processes described herein may be incorporated into a more comprehensive procedure or process having additional functionality not described in detail herein. In particular, various processes in the manufacture of integrated circuits are well-known and so, in the interest of brevity, many conventional processes are only mentioned briefly herein or omitted entirely without providing the well-known process details.

As will be readily apparent to those skilled in the art upon a complete reading of the present application, the semiconductor devices and methods disclosed herein may be employed in manufacturing a variety of different integrated circuit products and modules, including, but not limited to, CMOS devices, image sensors, optoelectronic modules, LIDAR instrumentation and LIDAR systems, etc.

What is claimed is:

1. A structure comprising:
a substrate;
an optical detector upon the substrate; and
an electrode upon an upper surface of the optical detector,
the electrode defining at least one aperture configured to filter electromagnetic waves traversing the aperture, wherein the optical detector is structured to detect the electromagnetic waves filtered by the aperture.

2. The structure of claim 1, wherein the electrode comprises a conductive barrier layer arranged directly on the upper surface of the optical detector, and a metal layer arranged upon the conductive barrier layer.

3. The structure of claim 2, further comprising a silicide layer arranged upon the upper surface of the optical detector, wherein the conductive barrier is arranged directly on the silicide layer.

4. The structure of claim 2, wherein the conductive barrier layer includes titanium nitride.

5. The structure of claim 2, wherein the metal layer includes copper.

6. The structure of claim 1, wherein the optical detector includes a diode.

7. The structure of claim 1, wherein the aperture is filled with a dielectric material having a refractive index in the range of 1.46 to 2.

8. The structure of claim 1, wherein the aperture comprises a cross-shaped aperture with rounded tips.

9. The structure of claim 1, wherein the aperture comprises a pair of elliptical openings that intersect with each other.

10. The structure of claim 1, wherein the electrode defines a plurality of apertures arranged in a matrix arrangement.

11. The structure of claim 10, wherein the plurality of apertures has a periodic arrangement.

12. A semiconductor device comprising:
a substrate;
an optical detector upon the substrate;
an electrode upon an upper surface of the optical detector,
the electrode defining at least one aperture configured to filter electromagnetic waves traversing the aperture, wherein the optical detector is structured to detect the electromagnetic waves filtered by the aperture;
a dielectric material that fills the aperture; and
a logic device component electrically connected to the optical detector.

13. The semiconductor device of claim 12, wherein the logic device component is a light to digital convertor.

14. The semiconductor device of claim 12, wherein the logic device component includes a transistor.

15. The semiconductor device of claim 12, wherein the substrate is a first substrate and further comprising the logic device component being arranged on a second substrate.

16. The semiconductor device of claim 12, wherein the logic device component is arranged on the same substrate as the optical detector.

17. A method of forming a semiconductor device comprising:
forming an optical detector on a substrate;
forming an electrode upon an upper surface of the optical detector, the electrode defining at least one aperture configured to filter electromagnetic waves traversing the aperture, wherein the optical detector detects the electromagnetic waves filtered by the aperture; and
connecting a logic device component with the optical detector.

18. The method of claim 17, wherein the forming of the electrode further comprises:
forming a dielectric layer upon the upper surface of the optical detector;
forming openings in the dielectric layer;
forming a conductive barrier layer within the openings in the dielectric layer; and
forming a metal layer upon the conductive barrier layer.

19. The method of claim 18, wherein the forming of the electrode further comprises forming a silicide layer on the upper surface of the optical detector before forming the dielectric layer upon the upper surface of the optical detector.

20. The method of claim 17, wherein the forming of the optical detector includes doping an upper surface of the substrate.
